(19) United States
(12) Patent Application Publication
(10) Pub. No.: US 2024/0105864 A1
(43) Pub. Date: Mar. 28, 2024

(54) GERMANIUM PHOTODIODE WITH OPTIMISED METAL CONTACTS

(71) Applicant: COMMISSARIAT A L'ENERGIE ATOMIQUE ET AUX ENERGIES ALTERNATIVES, Paris (FR)

(72) Inventors: Abdelkader ALIANE, Grenoble Cedex 09 (FR); Hacile KAYA, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/264,502

(22) PCT Filed: Feb. 9, 2022
(86) PCT No.: PCT/EP2022/053073

§ 371 Date: Aug. 7, 2023

(30) Foreign Application Priority Data
Feb. 11, 2021 (FR) 2101290

(51) Int. Cl. H01L 31/0224; H01L 31/028; H01L 31/105; H01L 31/18

(52) U.S. Cl. CPC H01L 31/022408; H01L 31/028; H01L 31/105; H01L 31/1808

(57) ABSTRACT

A photodiode including a detection portion made of a first germanium-based crystalline semiconductor material, including a first doped region, a second doped region, and an intermediate region; an interposed portion, in contact with the first doped region, made of a crystalline semiconductor material having a natural lattice parameter equal, to within 1%, to a natural lattice parameter of the first semiconductor material, and a bandgap energy at least 0.5 eV higher than that of the first semiconductor material.

### TECHNICAL FIELD

The field of the invention is that of passivated planar photodiodes produced from germanium comprising optimized metal contacts. The invention is notably applicable in the field of detecting light radiation in the near-infrared domain.

### PRIOR ART

Optoelectronic photodetection devices can comprise a matrix of passivated planar photodiodes. The photodiodes then extend along the same main plane, between first and second surfaces that are opposite and parallel to each other. They then each comprise a detection portion, formed, for example, from a first region made of n-doped germanium and flush with the first surface, from a second region made of p-doped germanium and flush with the second surface, and an intermediate region made of intrinsic or very low p-doped germanium, and located between the first and second doped regions. A passivation layer made of a dielectric material can cover the first surface in order to limit the contribution of the dark current to the electric current measured by each photodiode.

Electrical biasing of the first n-doped region and of the second p-doped region can, in the case of passivated planar photodiodes, be carried out on the side of the first surface. Thus, a peripheral semiconductor portion, for example made of p-doped polycrystalline silicon, surrounds the detection portion in a main plane of the photodiode and comes into contact with the second p-doped region. In addition, metal contacts, disposed on the side of the first surface, come into contact with the first n-doped region and the p-doped peripheral semiconductor portion.

However, it appears that a metal contact on n-doped germanium is of the rectifier type and not of the ohmic type, due to Fermi level pinning at the metal/germanium interface. However, various solutions exist for making the metal/n-doped germanium contact ohmic.

Thus, the document by Paramahans et al., entitled, “Contacts on n-type germanium using variably doped zinc oxide and highly doped indium tin oxide interfacial layers”, Appl. Phys. Express 8, 051302 (2015), describes interposing a very thin dielectric layer between the metal and the n-doped germanium, such as, for example, ZnO that is at least 2 nm thick, or ITO that is at least 2.4 nm thick. Moreover, the document by Wu et al., entitled, “Contact to n-type Ge with compositional Ti nitride”, Appl. Surf. Sc. 284, 877-880 (2013), describes another solution that involves producing a TiNₓ/n-Ge type contact, with x being at least equal to 0.8 in order to achieve an ohmic contact. However, these ohmic contacts then can be highly resistive, which degrades the performance capabilities of the photodiode.

Furthermore, document EP 3657556 A1 describes a passive planar photodiode made from germanium, in which an interposed semiconductor portion of n-doped polycrystalline silicon is formed on and in contact with the detection portion. It forms a reservoir of n-type dopants intended to diffuse into the germanium in order to produce the first n-doped region. A metal contact is produced on and in contact with the interposed semiconductor portion, and allows the first n-doped region to be electrically biased.

However, a need exists for providing such a passivated planar photodiode with improved performance capabilities.

### DISCLOSURE OF THE INVENTION

The aim of the invention is to at least partly overcome the disadvantages of the prior art and, more specifically, to propose a passivated planar photodiode that has improved performance capabilities.

To this end, the subject matter of the invention is a photodiode comprising:
a detection portion, having a first surface and a second surface opposite each other and parallel to a main plane, made of a first germanium-based crystalline semiconductor material, comprising:
   a first n-type doped region, and flush with the first surface;
   a second p-type doped region, and flush with the second surface;
   an intermediate region, located between the first region and the second region and surrounding the first region in the main plane;
a peripheral semiconductor portion, made of a second p-type doped semiconductor material, surrounding the detection portion in the main plane and coming into contact with the second region;
an interposed semiconductor portion, disposed on and in contact with the first region of the detection portion;
metal contacts, disposed on the side of the first surface, and adapted to electrically bias, on the one hand, the first region by means of the interposed semiconductor portion and, on the other hand, the second region by means of the peripheral semiconductor portion.

According to the invention, the interposed semiconductor portion is made of a third crystalline semiconductor material having: a natural lattice parameter equal, to within 1%, to a natural lattice parameter of the first germanium-based semiconductor material; and a bandgap energy at least 0.5 eV higher than that of the first germanium-based semiconductor material.

Some preferred but non-limiting aspects of this photodiode are as follows.

The interposed semiconductor portion can comprise n-type dopants identical to those present in the first region.

The interposed semiconductor portion can be made of a III-V crystalline semiconductor compound, and preferably of AlAs or GaAs.

The interposed semiconductor portion can be located in a notch of the first surface of the detection portion so that the interposed semiconductor portion is surrounded, in the main plane, by the first region.

One of the metal contacts, called central metal contact, can be located on and in contact with the intermediate semiconductor portion.

The photodiode can comprise an upper semiconductor portion located on and in contact with the interposed semiconductor portion, made of an n-type doped semiconductor material with dopants identical to those of the interposed semiconductor portion and of the first region.

One of the metal contacts, called central metal contact, then can be located on and in contact with the upper semiconductor portion.

The upper semiconductor portion can be made of a material identical to that of the peripheral semiconductor portion.

The upper semiconductor portion and the peripheral semiconductor portion can be made of a silicon-based semiconductor material. The photodiode can then comprise a silicided upper zone in contact with the metal contacts.

The invention also relates to a method for manufacturing a photodiode according to any one of the preceding features, comprising the following steps:
producing a stack comprising a first sub-layer intended to form the second region and a second sub-layer intended to form the intermediate region;
producing an upper insulating layer covering the stack;
producing the peripheral semiconductor portion through the stack and the upper insulating layer in order to emerge onto the first sub-layer;
producing the interposed semiconductor portion by epitaxy from the second sub-layer of the stack, through an opening of the upper insulating layer.

The method can comprise, before the step of producing the interposed semiconductor portion, a step of producing a notch in the second sub-layer of the stack, through the opening, followed by epitaxy of the interposed semiconductor portion in the notch.

When the interposed semiconductor portion is unintentionally doped during the epitaxy thereof, the method can then comprise the following steps:
producing the n-type doped upper semiconductor portion;
annealing adapted to cause diffusion of the dopants contained in the upper semiconductor portion through the interposed semiconductor portion in order to form the first region in the detection portion.

The upper semiconductor portion and the peripheral semiconductor portion can be made of the same silicon-based material. The method can then comprise a step of simultaneously producing metal contacts, one in contact with the upper semiconductor portion, and the other in contact with the peripheral semiconductor portion.

The interposed semiconductor portion can be n-type doped during the epitaxy thereof. The method can then comprise the following step: producing metal contacts, one in contact with the interposed semiconductor portion, and the other in contact with the peripheral semiconductor portion.

### BRIEF DESCRIPTION OF THE DRAWINGS

Further aspects, aims, advantages and features of the invention will become more dearly apparent upon reading the following detailed description of preferred embodiments thereof, which are provided by way of a non-limiting example and with reference to the appended drawings, in which:

FIG. 1A is a schematic and partial cross-sectional view of a passivated planar photodiode according to one embodiment, comprising a metal contact in contact with the interposed semiconductor portion, which is in contact with the first region of the detection portion;

FIG. 1B is a schematic and partial cross-sectional view of a passivated planar photodiode according to an alternative embodiment, comprising an upper semiconductor portion disposed between and in contact with the metal contact and the interposed semiconductor portion;

FIGS. 2A to 2L illustrate various steps of a method for manufacturing a photodiode according to the embodiment illustrated in FIG. 1B;

FIGS. 3A to 3C illustrate various steps of a method for manufacturing a photodiode according to the embodiment illustrated in FIG. 1A.

### DETAILED DISCLOSURE OF PARTICULAR EMBODIMENTS

In the figures and throughout the remainder of the description, the same reference signs represent identical or similar elements. In addition, the various elements are not shown to scale so as to enhance the clarity of the figures. Moreover, the various embodiments and alternative embodiments are not mutually exclusive and can be combined with one another. Unless otherwise stated, the terms “substantially”, “approximately”, “of the order of” mean to within 10%, and preferably to within 5%. Moreover, the terms “ranging between . . . and . . . ” and equivalent terms mean that the limits are inclusive, unless otherwise stated.

The invention generally relates to a passivated planar photodiode, and preferably to a matrix of photodiodes, as well as to the manufacturing method. Each photodiode comprises a detection portion produced from germanium, and is adapted to detect light radiation in the near-infrared domain (SWIR, Short Wavelength IR) corresponding to the spectral range ranging from 0.8 μm to approximately 1.7 μm, or even to approximately 2.5 μm.

The detection portion of the photodiodes has a first surface and a second surface opposite each other and parallel to a main plane of the photodiodes. The two surfaces extend along identical planes for each of the photodiodes, and vertically delimit (along the thickness axis) the detection portion. The photodiodes do not have a mesa structure insofar as they are optically insulated from one another by peripheral trenches filled with a doped semiconductor material. They thus have a particularly high fill factor. Moreover, they are said to be passivated insofar as the first surface is partly covered by a dielectric passivation layer. This helps to reduce the surface component of the dark current.

In general, the photodiode comprises:
a detection portion, made of a first germanium-based crystalline semiconductor material, comprising: a first n-type doped region, a second p-type doped region and an intermediate region located between the two doped regions and surrounding the first doped region in a main plane of the photodiode;
a peripheral semiconductor portion, made of a second p-type doped semiconductor material, surrounding the detection portion in the main plane and coming into contact with the second doped region;
an interposed semiconductor portion, disposed on and in contact with the first n-doped region, and made of an n-doped crystalline semiconductor material, and coming into contact with the first n-doped region;
metal contacts, disposed on the side of the first surface, and adapted to electrically bias, on the one hand, the first region by means of the interposed semiconductor portion and, on the other hand, the second region by means of the peripheral semiconductor portion.

The crystalline semiconductor material of the interposed semiconductor portion has a natural lattice parameter equal to that of the first germanium-based semiconductor material to within 1%, i.e. it is equal to plus or minus 1%, and preferably to within 0.5%. The term “natural lattice parameter” is understood to mean the lattice parameter of the unconstrained material, i.e. relaxed. The relevant lattice parameter in this case is oriented in the main plane of the photodiode. In addition, the crystalline semiconductor material of the interposed semiconductor portion has a bandgap energy that is at least 0.5 eV higher than that of the first germanium-based semiconductor material. The bandgap energy corresponds to the energy difference between the minimum energy of the conduction band and the maximum energy of the valence band. The crystalline semiconductor material of the interposed semiconductor portion preferably is a III-V compound, for example a binary III-V compound, such as AlAs and GaAs, or even a ternary III-V compound, such as GaAlAs or GaInP.

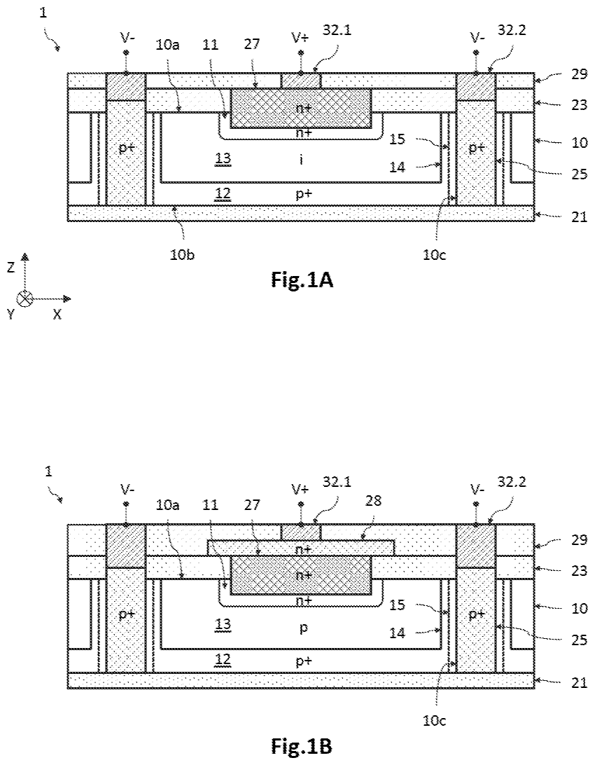

FIG. 1A is a partial and schematic cross-sectional view of a passivated planar photodiode 1 according to one embodiment, forming part of a matrix of photodiodes. The photodiodes 1 are produced from germanium, and are reverse biased from the first surface 10a, while being insulated from one another by trenches filled with a p+ doped semiconductor material. They each comprise an interposed semiconductor portion 27, in this case located between and in contact with a metal contact 32.1 for electrical biasing and the first n+ doped region 11.

Herein, and for the remainder of the description, a direct three-dimensional coordinate system XYZ is defined, where the X and Y axes form a plane parallel to the main plane of the photodiode 1, and where the Z axis is oriented along the thickness of the detection portion 1 of the photodiode, from the second surface 10b toward the first surface 10a.

The photodiode 1 comprises a detection portion 10 extending along the Z axis between a first and a second reference surface 10a and 10b, parallel to each other and opposite each other. The first surfaces 10a of the photodiodes are parallel to each other, and the second surfaces 10b are also parallel to each other. The first surface 10a is defined by part of the detection portion 10 where the first n+ doped region 11 is flush, as well as the intermediate region 13. The second surface 10b is opposite the first surface 10a along the Z axis.

The maximum thickness of the detection portion 10, defined along the Z axis between the first and second surfaces 10a, 10b, in this case is substantially constant from one photodiode to the next, for example ranges between a few hundred nanometers and a few microns, for example between approximately 1 μm and 5 μm. The thickness is selected so as to achieve good absorption in the wavelength range of the light radiation to be detected. The detection portion 10 has a transverse dimension in the XY plane that can range between a few hundred nanometers and a few tens of microns, for example ranging between approximately 1 μm and approximately 20 μm.

The detection portion 10 is made of a germanium-based crystalline semiconductor material, preferably monocrystalline. The term “germanium-based” means that the crystalline semiconductor material corresponds to germanium or is a compound at least formed by germanium. Thus, the photodiodes can be produced, for example, from germanium Ge, silicon germanium SiGe, germanium tin GeSn, or even silicon germanium tin SiGeSn. In this example, the detection portion 10 is derived from at least one layer made of germanium. It thus can be a layer or a substrate made of the same semiconductor material and can have regions with different types of conductivity (homojunction) so as to form a PN or PIN junction. It can, as an alternative embodiment, be a stack of sub-layers of different semiconductor materials (heterojunction), which are then formed from germanium.

The detection portion 10 is thus formed of a first n-type doped region 11 (n or n+), which is flush with the first surface 10a and forms an n-type doped chamber, and a second p+ doped region 12, which is flush with the second surface 10b. The term “flush” is understood to mean “reaches the level of”, or “extends from”. An unintentionally doped intermediate region 13 (in the case of a PIN junction), or a p-doped region (in the case of a PN junction), is located between and in contact with the two doped regions 11 and 12, and surrounds the first n+ doped region 11 in the main plane. In this example, the semiconductor junction is of the PIN type, with the first region 11 being n+ type doped, the second region 12 being p+ type doped and the intermediate region 13 being intrinsic (unintentionally doped).

The first n-type doped region 11 in this case extends from the first surface 10a and is surrounded by the intrinsic region 13 in the main plane. It is remote from the lateral edge 10c of the detection portion 10 in the XY plane, with the lateral edge 10c being defined by the internal face of a p+ doped peripheral semiconductor portion 25. It thus forms an n+ doped chamber that is flush with the first surface 10a and is spaced apart by a non-zero distance with respect to the lateral edge 10c, as well as the second surface 10b. The first n+ doped region 11 thus helps to delimit the first surface 10a. It can have doping that can range between approximately 5.10¹⁸ and 10²¹ at/cm³.

The second p+ doped region 12 extends in the XY plane flush with the second surface 10b, in this case from the lateral edge 10c. It extends along the Z axis from the second surface 10b. It can have a substantially homogeneous thickness along the Z axis and thus only be flush with a lower zone of the lateral edge 10c. As an alternative embodiment, as illustrated in FIGS. 1A and 1B, the second p+ doped region 12 can have a p+ doped lateral region 14 that is continuously flush with the lateral edge 10c along the Z axis and extends over the entire periphery of the detection portion 10. The second p+ doped region 12 can have doping that can range between approximately 10¹⁸ and 10¹⁹ at/cm³.

The intermediate region 13 is located between the two n+ and p+ doped regions 11, 12, and surrounds the first n+ doped region 11 in the XY plane. In this case, it is made of an intrinsic semiconductor material so as to form a PIN junction, but can be lightly p-doped, in order to form a PN junction (see FIG. 1B).

The photodiode 1 in this case comprises a lower insulating layer 21, made of a dielectric material, covering the second surface 10b of the detection portion 10, as well as, as described hereafter, the lower face of the p+ doped peripheral semiconductor portion 25. The lower insulating layer 21 also can be adapted to form an antireflection function with respect to the incident light radiation. It actually forms the reception face of the light radiation intended to be detected.

The detection portion 10 of the photodiode 1 in this case is laterally delimited, in the XY plane, by a preferably continuous trench, filled with a p+ doped semiconductor material, and forming a peripheral semiconductor portion 25, which in this case is p+ doped. The peripheral through portion 25 helps to electrically bias the photodiode 1, in this case from the side of the first surface 10a, and to pixelate the matrix of photodiodes (optical insulation). In this case, it extends over the entire thickness of the detection portion 10 in order to emerge onto the lower insulating layer 21, but, as an alternative embodiment, it may not emerge onto the lower insulating layer 21 and can end in the second p+ doped region 12. The inner face of this p+ doped peripheral semiconductor portion 25 then defines the lateral edge 10c of the detection portion 10. The semiconductor material is preferably made of silicon, for example of amorphous silicon, of polycrystalline silicon, of silicon germanium, or even can be made of amorphous germanium.

An upper insulating layer 23 covers the first surface 10a of the photodiode 1, and allows the metal contacts 32.1 and 32.2 to be electrically insulated. It is thus in contact with the first n+ doped region 11, as well as the intermediate region 13. It is made of a dielectric material, such as a silicon oxide, a silicon nitride, or a silicon oxynitride. Other dielectric materials can be used, such as a hafnium or aluminum oxide, or even an aluminum nitride, among others. Its thickness ranges, for example, between 50 nm and 500 nm.

Furthermore, the detection portion 10 advantageously comprises a p+ type doped lateral region 14 located in the vicinity of the lateral edge 10c. This lateral region 14 has a doping level higher than that of the intermediate region 13 when it is doped. The p+ doped lateral region 14 is flush with the lateral edge 10c and is in contact with the p+ doped peripheral semiconductor portion 25. Thus, the biasing of the second p+ doped region 12 is improved insofar as the contact surface with the p+ doped peripheral semiconductor portion 25 is increased. In addition, this p+ doped lateral region 14 prevents the space charge zone of the photodiode 1 from extending to the lateral edge 10c. Thus, the contribution of this zone (potentially not exempt of defects associated with the production of trenches) to the dark current is limited. This thus improves the performance capabilities of the photodiode 1.

Furthermore, the detection portion 10 is made from germanium, for example is made of germanium, and the p+ doped peripheral semiconductor portion 25 is made from silicon, for example of doped polycrystalline silicon. The detection portion 10 then advantageously comprises a lateral zone 15 made from silicon germanium. The lateral zone 15 is flush with the lateral edge 10c and is in contact with the p+ doped peripheral semiconductor portion 25. Thus, the lateral zone 15 has a bandgap energy (gap) greater than that of the detection portion 10 made of germanium. This “opening of the lateral gap” reduces the sensitivity of the photodiode 1 to any defects present in the vicinity of the trenches. This thus improves the performance capabilities of the photodiode 1.

Furthermore, the photodiode 1 comprises an interposed semiconductor portion 27, disposed on and in contact with the first n+ doped region 11. It is spaced apart by a non-zero distance from the peripheral semiconductor portions 25 in the XY plane and in this case is surrounded by the upper insulating layer 23. It is made of a doped crystalline semiconductor material, in this case of the n+ type, which has a natural lattice parameter that is equal, to within 1%, and preferably to within 0.5%, to that of the crystalline semiconductor material of the detection portion 10, in this case germanium, and has a bandgap energy that is at least 0.5 eV higher than that of the crystalline semiconductor material of the detection portion 10 (germanium). The interposed semiconductor portion 27 thus can be made of a binary or ternary compound III-V, such as GaAs, AlAs, GaAlAs, GaInP, among others.

In this example, the interposed semiconductor portion 27 is advantageously located in a notch formed in the first surface 10a of the detection portion 10, which reduces or even avoids the presence of structural defects (dislocations) in the intermediate portion 27, as described hereafter. As an alternative embodiment, it can rest on the first surface 10a, which is then continuously planar (no notch). The size of the interposed semiconductor portion 27 in the XY plane depends on the size of the photodiode 1: for a photodiode with a pitch of 5 μm, it can range between approximately 0.5 and 4 μm (and preferably less than 2 μm), and for a pitch of 10 μm, it can range between approximately 1 and 9 μm.

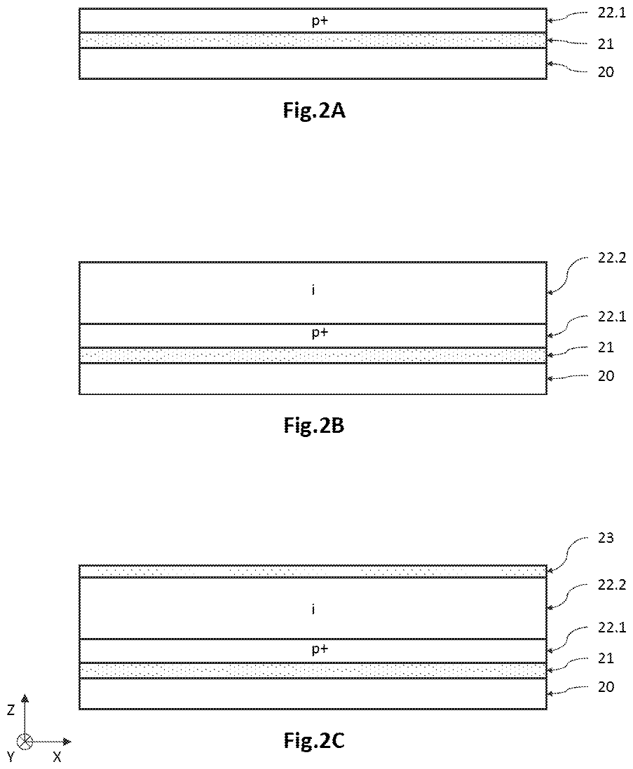

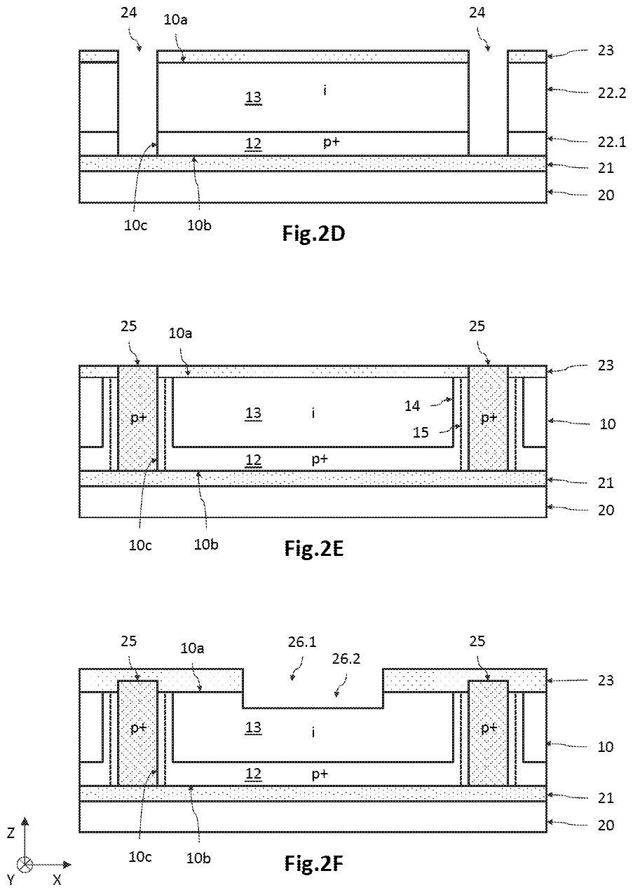

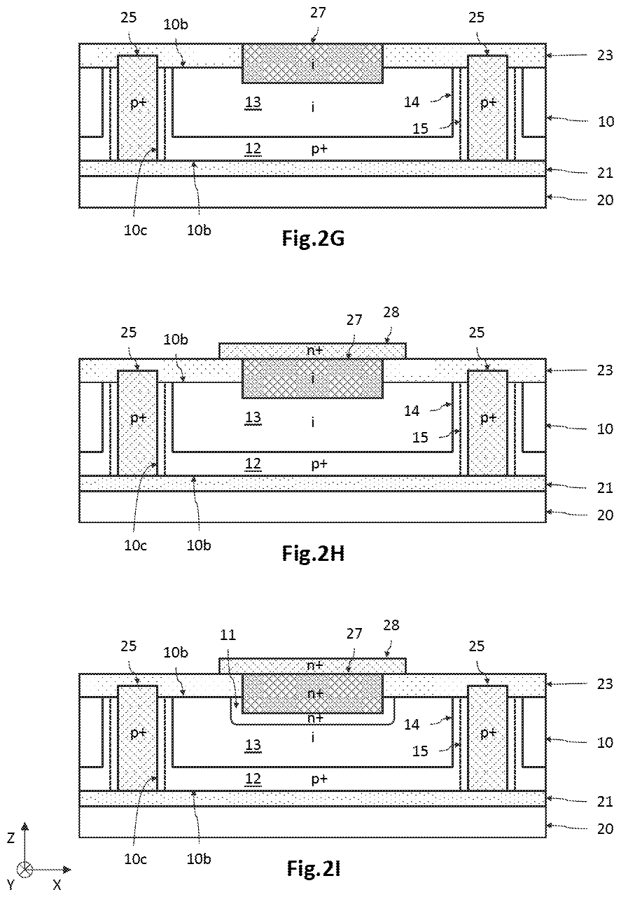

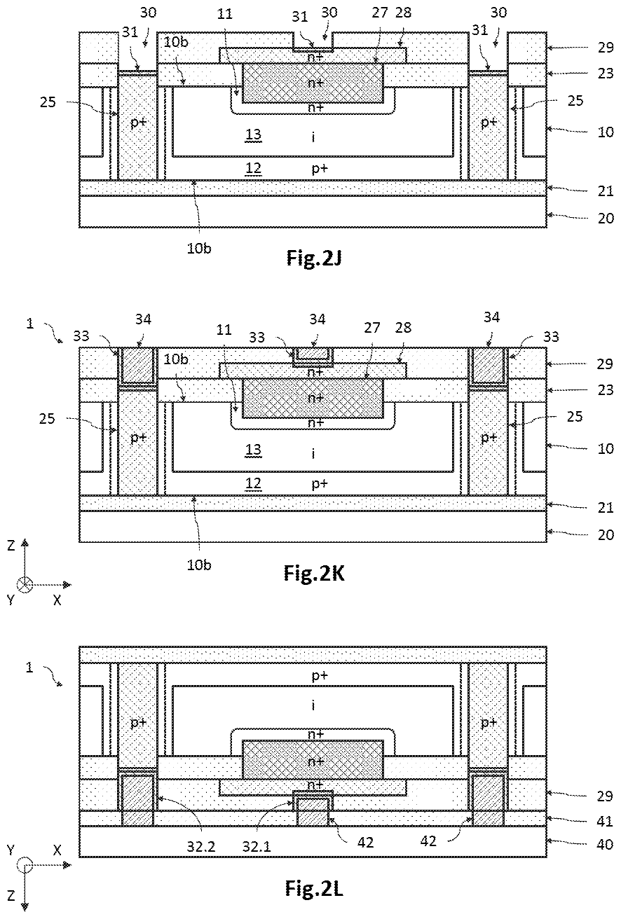

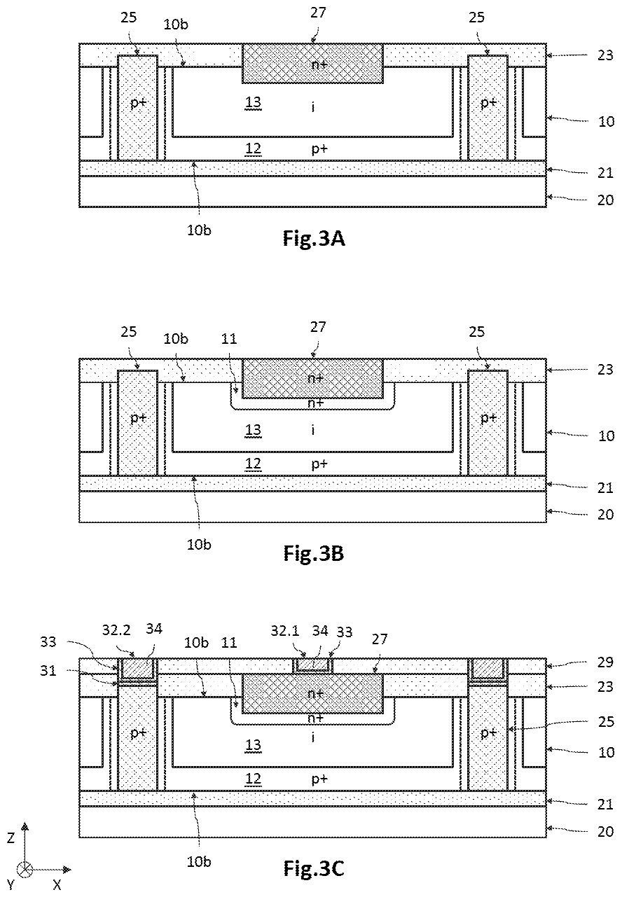

It should be noted here that the interposed semiconductor portion 27 comprises n-type dopants identical to those present in the first n+ doped region 11, insofar as, as explained hereafter, the formation of the first region 11 is carried out by diffusing the dopants through the interposed semiconductor portion 27 (see FIGS. 2A to 2L) or initially contained in the interposed semiconductor portion 27 (FIGS. 3A to 3C).

The photodiode 1 further comprises metal contacts 32.1, 32.2 allowing reverse biasing from the side of the first surface 10a. Thus, a metal contact 32.1 in this case is disposed on and in contact with the interposed semiconductor portion 27, and allows electrical biasing of the first n+ doped region 11. A metal contact 32.2 in this case is disposed on and in contact with the peripheral semiconductor portion 25, and allows electrical biasing of the second p+ doped region 12. The metal contacts 32.1, 32.2 in this case are electrically insulated from one another in the XY plane by the upper insulating layer 23 and by a dielectric passivation layer 29. The photodiode 1 is intended to be reverse biased, for example by applying a negative electrical potential to the p+ doped peripheral semiconductor portion 25 and by conveying the first n+ doped region 11 to ground.

In general, by way of an illustration, the photodiode 1 can have dimensions in the XY plane ranging approximately between 1 μm and 100 μm. The thickness of the second p+ doped region 12 can range approximately between 20 nm and 500 nm. The thickness of the intrinsic region 13 can range approximately between 0.7 μm and 2.5 μm when the photodiode 1 is intended to detect light radiation in the SWIR or near-infrared (NIR) range. The thickness of the first n+ doped region 11 can range between approximately 10 nm and 600 nm. The dielectric layers 23 and 29 can together have a thickness that allows the upper face of the photodiode 1 to be fully covered, for example ranging between approximately 10 nm and 600 nm, and the thickness of the lower insulating layer 21 can range between approximately 50 nm and 1 μm.

Thus, the photodiode 1 has improved performance capabilities compared to the aforementioned examples of the prior art. Indeed, the photodiode 1, by the presence of the interposed semiconductor portion 27 located between the metal contact 32.1 and the n-doped germanium 11, does not include a metal contact on the n-doped germanium (first region), which would then form a rectifier contact, or even a highly resistive ohmic contact. The series resistances are thus limited, which notably allows the low-frequency noise to be limited. In addition, the interposed semiconductor portion 27, which is in contact with the first n+ doped region 11, is made of a semiconductor material with a bandgap energy that is at least 0.5 eV higher than that of germanium, which allows the dark current of the photodiode 1 to be reduced, on the one hand, and allows the sensitivity of the photodiode 1 to any defects possibly present in the vicinity of the notch in which the interposed semiconductor portion 27 is located to be reduced, on the other hand. In addition, the lack of mismatching of the lattice parameter between the crystalline material of the interposed semiconductor portion 27 and that of the detection portion 10 allows any structural defects (dislocations, etc.) to be avoided that would degrade the performance capabilities of the photodiode 1.

FIG. 1B is a schematic and partial cross-sectional view of a photodiode 1 according to an alternative embodiment. In this example, the photodiode 1 differs from that illustrated in FIG. 1A, notably in that the intermediate region 13 is lightly p-doped (PN junction), and in that an upper semiconductor portion 28 is located between and in contact with the central metal contact 32.1 and the interposed semiconductor portion 27.

More specifically, the interposed semiconductor portion 27, as indicated above, rests on and in contact with the detection portion 10. It is thus in contact with the first n+ doped region 11. It is made of a crystalline semiconductor material having the properties mentioned above in terms of bandgap energy and lack of lattice mismatching with the germanium of the detection portion 10. As indicated hereafter, it has been produced by epitaxy from germanium and in an unintentionally doped manner.

The upper semiconductor portion 28 therefore rests on and in contact with the interposed semiconductor portion 27. It is spaced apart from the peripheral semiconductor portion 25 and the metal contacts 32.2 in the XY plane by a non-zero distance. This lateral space in this case is filled by the dielectric passivation layer 29. The upper semiconductor portion 28 is made of an n+ doped semiconductor material with dopants capable of n+ doping the germanium in order to form the first n+ doped region 11, in this case with phosphorus or arsenic. Thus, the upper semiconductor portion 28 is a reservoir of dopants intended to diffuse, during diffusion annealing, through the interposed semiconductor portion 27 in order to join the germanium and form the first n+ doped region 11. It is preferably made from polycrystalline silicon, but other polycrystalline materials clearly can be used.

Finally, the metal contact 32.1 in this case is disposed on and in contact with the upper semiconductor portion 28. It allows electrical biasing of the first n+ doped region 11 via the upper semiconductor portion 28 and then of the interposed semiconductor portion 27.

FIGS. 2A to 2L are schematic and partial cross-sectional views of various steps of a method for manufacturing a photodiode according to the example of FIG. 1B. This method in this case notably has the advantage of producing metal contacts 32.1 and 32.2 simultaneously. It also has the advantage of not implementing doping of the interposed semiconductor portion 27 at the growth (controlling the diffusion of the dopants can be delicate) or by ion implantation (which can create defects in the interposed semiconductor portion 27).

In this example, the photodiodes 1 are made of germanium and comprise a PIN junction, and are adapted to detect infrared radiation in the SWIR range. The photodiodes 1 are planar and passivated, and are reverse biased from the first surface 10a, and in this case by means of a control chip 40 hybridized to the matrix of photodiodes 1.

With reference to FIG. 2A, a first semiconductor sub-layer 22.1 of monocrystalline germanium is produced. The first semiconductor sub-layer 22.1 is secured to a support layer 20, in this case made of silicon, by means of a lower insulating layer 21, in this case made of a silicon oxide. This stack assumes the form of a GeOI (Germanium-On-Insulator) substrate. This stack is preferably produced by means of the method described in the publication by Reboud et al., entitled, “Structural and optical properties of 200 mm germanium-on-insulator (GeOI) substrates for silicon photonics applications”, Proc. SPIE 9367, Silicon Photonics X, 936714 (Feb. 27, 2015). Such a method has the advantage of producing a germanium semiconductor sub-layer 22.1 having a total lack or a low level of structural defects such as dislocations. The germanium can be unintentionally doped or can be doped, for example of the p-type. The thickness of the semiconductor sub-layer 22.1 can range approximately between 100 nm and 500 nm, for example can be equal to approximately 300 nm, and can be covered with a protective layer (not shown) made of a silicon oxide. The thickness of the lower insulating layer 21 (BOX, Buried Oxide) can range between 50 nm and 1 μm, for example it can range between 100 nm and 500 nm, and advantageously provides an antireflection function.

Doping of the first sub-layer 22.1 made of p+ doped germanium is then carried out, by ion implantation of a dopant, such as boron or gallium, when the first sub-layer 22.1 was initially made of intrinsic germanium. The protective layer, where appropriate, has been removed beforehand by surface cleaning, and the first sub-layer 22.1 of germanium can be coated with a pre-implantation oxide layer (not shown) with a thickness of a few tens of nanometers, for example equal to 20 nm. The sub-layer 22.1 of germanium then has a doping level ranging between approximately 10¹⁸ and 10²⁰ at/cm³. Diffusion annealing of the dopant then can be carried out under nitrogen, for a few minutes to a few hours, for example 1 hour, at a temperature that can range between 600° C. and 800° C., for example equal to 800° C. This annealing may not be carried out when the sub-layer 22.1 was doped at the growth. Another way of manufacturing this p+ layer is by epitaxy of a layer of germanium doped with boron in situ between approximately 10¹⁸ and 10¹⁹ at/cm³ on an intrinsic germanium sub-layer. This epitaxy can be carried out between 400 and 800° C., but preferably at 400° C.

With reference to FIG. 2B, a second semiconductor sub-layer 22.2 of germanium is produced by epitaxy from the first sub-layer 22.1. The two sub-layers 22.1, 22.2 are intended to form the coplanar germanium detection portions 10 of the matrix of photodiodes 1. The second sub-layer 22.2 is formed by epitaxy, for example by chemical vapor deposition (CVD) and reduced pressure precedence (RPCVD, Reduced Pressure Chemical Vapor Deposition) or by any other epitaxy technique. Annealing can be carried out in order to decrease the rate of dislocations in the sub-layer 22.2. The pre-implementation oxide layer, where appropriate, has been removed beforehand by surface cleaning. The second sub-layer 22.2 of germanium is intrinsic in this case, i.e. unintentionally doped insofar as the intention is to produce a PIN junction. It is intended to form the light absorption zone of the photodiodes 1. Its thickness depends on the wavelength range of the light radiation to be detected in the case of a photodiode 1. Within the context of SWIR photodiodes, the thickness of the sub-layer 22.2 of intrinsic germanium ranges, for example, between 0.5 μm and 3 μm, and preferably is equal to 1.5 μm.

With reference to FIG. 2C, an upper insulating layer 23 is deposited so as to continuously cover the upper face of the second sub-layer 22.2, i.e. so as to cover the detection portions 10 of the photodiodes 1. The upper insulating layer 23 is made of a dielectric material, for example an oxide, a nitride or a silicon oxynitride. Cleaning of the upper face of the second sub-layer 22.2 may have been carried out beforehand. The thickness of the upper insulating layer 23 can range between 10 nm and 600 nm.

With reference to FIG. 2D, the trenches 24 are produced by photolithography and etching, which trenches are intended to pixelate the photodiodes 1 and to participate in the reverse electrical biasing (by means of the peripheral semiconductor portions 25 that will then be produced). Localized etching of the upper insulating layer 23, of the intrinsic germanium sub-layer 22.2, and of the p+ doped germanium sub-layer 22.1 is thus carried out, until in this case it emerges onto the upper face of the lower insulating layer 21 (but the trenches 24 can emerge onto the sub-layer 22.1 without passing through it). Each trench 24 thus preferably continuously extends around a photodiode 1. Thus, a plurality of detection portions 10 separated from one another by a continuous trench 24 are acquired. They are preferably acquired using an anisotropic etching technique, so as to acquire a substantially vertical lateral edge 10c along the Z axis. The trenches 24 have a transverse dimension (width) in the XY plane that can range between 300 nm and 2 μm, for example equal to 1 μm. The detection portions 10 thus can assume a shape in the XY plane, for example a circular, oval, polygonal, for example square, or any other shape.

With reference to FIG. 2E, the peripheral semiconductor portions 25 are then produced. To this end, a doped semiconductor material is deposited so as to fill the trenches 24. The semiconductor material preferably is a silicon-based material, for example amorphous silicon, polycrystalline silicon, silicon germanium, or even amorphous germanium. The semiconductor material is p+ doped with boron or gallium, with a dopant concentration of the order of approximately 10¹⁹ to 10²⁰ at/cm³. Thus, the doped semiconductor material comes into contact with the lateral edge 10c via the trench 24. A chemical mechanical polishing (CMP) step is then carried out, stopping on the upper face of the upper insulating layer 23 in order to eliminate the excess semiconductor material and planarize the upper face formed by the upper insulating layer 23 and the semiconductor material of the peripheral semiconductor portion 25. A p+ doped peripheral semiconductor portion 25 is thus acquired in each trench 24.

With reference to FIG. 2F, a dielectric layer is deposited so as to cover the upper surface of the peripheral semiconductor portions 25 (thus increasing the thickness of the upper insulating layer 23 that thus covers the portions 25). Then, by photolithography and etching, a through-opening 26.1 is produced within the upper insulating layer 23 in order to emerge onto the detection portion 10, facing a central zone located at a distance from the peripheral semiconductor portions 25 in the XY plane. The width or the diameter of the through-opening 26.1 notably depends on the desired width of the first n+ doped region. It can range between 0.3 μm and 5 μm, for example. Preferably, the through-opening 26.1 also forms a notch within the detection portion 10, for example with a depth of around one hundred nanometers.

With reference to FIG. 2G, an interposed semiconductor portion 27, located facing the central zone of the detection portion 10 and in contact with said portion, is produced. The interposed semiconductor portion 27 is produced by epitaxy, in this case from the germanium of the detection portion, for example by molecular jets (MBE, molecular beam epitaxy). It is made of a crystalline semiconductor material, which has, on the one hand, a lattice parameter almost identical to that of germanium, i.e. its natural lattice parameter is equal to that of germanium at most to within 1.0%, and preferably to 0.5% at most; and on the other hand, a bandgap energy Eg higher (i.e. strictly higher) than that, namely EgGe, of the germanium of the detection portion.

By way of an example, the interposed semiconductor portion 27 is made of AlAs or GaAs (stoichiometric compounds, i.e. the proportion of the two elements is identical, the natural lattice parameter of which is 5.6605 Å for AlAs and 5.653 Å for GaAs, which respectively corresponds to a difference of 0.044% and of 0.088% with the natural lattice parameter of 5.658 Å of germanium. In addition, the bandgap energy is 2.12 eV for AlAs and 1.424 eV for GaAs, which is much higher than the 0.67 eV of germanium. Other semiconductor compounds, for example ternary compounds, also can be suitable, such as, for example, GaAlAs and GaInP as a function of the proportions of the various chemical elements.

In this example, the interposed semiconductor portion 27 is intrinsic, i.e. unintentionally doped. The formation of the first n+ doped region 11 will be acquired by diffusing germanium dopants (for example, phosphorus or arsenic) from a dopant reservoir (the upper semiconductor portion 28) through the interposed semiconductor portion 27.

With reference to FIG. 2H, an upper semiconductor portion 28 is produced, forming the reservoir of n-type dopants intended to diffuse into the detection portion through the interposed semiconductor portion 27 in order to ultimately acquire the first n+ doped region 11. It is made of an n+ type doped semiconductor material, for example polysilicon or polycrystalline silicon germanium. However, it is advantageously made of a material identical to that of the peripheral semiconductor portion, for example in this case of polysilicon, so as to simplify the production of the metal contacts 32.1 and 32.2.

By way of an example, the upper semiconductor portion 28 is made of n+ doped polysilicon with phosphorus or arsenic, produced by low-pressure chemical vapor deposition (LPCVD) between 400° C. and 650° C., for example. Its size in the XY plane is preferably greater than that of the interposed semiconductor portion 27, and its thickness ranges between 50 nm and 200 nm, for example.

With reference to FIG. 2I, diffusion annealing and activation of the dopants is then carried out, for example between 500° C. and 800° C. and for approximately 10 to 60 minutes. Thus, the dopants (phosphorus or arsenic) diffuse through the interposed semiconductor portion 27 and then into the detection portion 10. A first n+ doped region 11 is thus acquired that extends in contact with the interposed semiconductor portion 27, in the Z axis as in the XY plane.

It should be noted that the fact that the interposed semiconductor portion 27 has been epitaxied in a notch 26.2 of the detection portion 10 means that it is possible to reduce the number of structural defects (dislocations) in the interposed semiconductor portion 27 or even to prevent them. Hence, the crystalline quality of the crystalline material is better, which improves the performance capabilities of the photodiode.

With reference to FIG. 2J, a dielectric passivation layer 29 is deposited so as to cover the upper semiconductor portion 28. The dielectric layer can be deposited at 400° C. and be made of a dielectric material, such as an oxide, silicon nitride or oxynitride, an aluminum oxide or nitride, a hafnium oxide, among others. The thickness thereof can range, for example, between 200 nm and 1,000 nm. A CMP type planarization step is then carried out.

The through-openings 30 are then made through the dielectric layers 23, 29 so as to emerge onto an upper surface of the peripheral semiconductor portion 25 (in order to then make the metal contact 32.2) and onto an upper surface of the upper semiconductor portion 28 (in order to then make the metal contact 32.1). The size of these through-openings 30 in the XY plane can range between 0.1 μm and 1 μm, preferably ranging between 0.3 μm and 1 μm. They can be produced by plasma etching, with etching stopping on the polysilicon surfaces of the upper semiconductor portion 28 and of the peripheral semiconductor portion 25. Thus, the fact that the upper portion 28 and the peripheral portion 25 are made of the same material, in this case of silicon, means that the metal contacts 32.1 and 32.2 can be produced simultaneously, thus simplifying the manufacturing method.

With reference to FIG. 2K, a silicided zone 31 of the upper surface of the upper semiconductor portion 28, and a silicided zone 31 of the upper surface of the peripheral semiconductor portion 25 are preferably produced. To this end, a thin film of the type formed by a 9 nm and 10 nm thick Ni/TiN stack is deposited at the bottom of the through-openings 30, 30 by physical vapor deposition (PVD), followed by silicidation annealing between approximately 300° C. and 350° C. for approximately 10 to 30 seconds. The unreacted Ni and TiN are then removed, then a second silicidation annealing step is carried out between approximately 400° C. and 450° C. for approximately 10 to 30 seconds.

The central 32.1 and lateral 32.2 metal contacts are then produced. In this case, a thin attachment layer 33 is deposited that is formed by a stack of the Ti/TiN/Cu type by value phase chemical vapor deposition in the through-openings 30.1, 30.2, and the empty space is filled with copper 34 deposited by electrolysis. A CMP type planarization step is then carried out, stopping on the oxide of the dielectric passivation layer 29. The dielectric passivation layer 29 and the metal contacts 32.1 and 32.2 together have the same planar upper face.

With reference to FIG. 2L, the optoelectronic stack thus acquired is hybridized on a control chip 40. The connection face of the control chip 40 thus can be coated with an insulating layer 41, made of a dielectric material, traversed by metal contacts 42. The matrix of photodiodes 1 and the control chip 40 are thus assembled by hybrid molecular bonding, by bringing into contact the formed faces of the metal contacts and of the insulating layers. Bonding annealing can be carried out so as to increase the surface bonding energy between the two contacting faces. The support layer 20 is then removed, for example by grinding, so as to expose the lower insulating layer 21. This lower insulating layer thus forms the reception face for the light radiation to be detected, and advantageously provides an antirefiection function.

The manufacturing method thus allows one or more passivated photodiodes 1 to be acquired, each comprising an interposed semiconductor portion 27 in contact with the detection portion 10, the properties of which in terms of lattice parameters and bandgap energy mean that it is possible to avoid having to make a metal contact directly on the n-doped germanium, with such a contact either being of the rectifier type, or of the ohmic type, but highly resistive. One or more photodiodes 1 with improved performance capabilities are thus produced, notably in terms of low-frequency noise (as indicated above).

FIGS. 3A to 3C are schematic and partial cross-sectional views of various steps of a method for manufacturing a photodiode 1 according to the example of FIG. 1A.

The photodiode 1 differs from that illustrated in FIG. 1B basically in that it does not comprise an upper semiconductor portion 28. Also, the metal contact 32.1 is on and in contact with the interposed semiconductor portion 27.

Also, the first n+ doped region 11 is produced by diffusing dopants from the interposed semiconductor portion 27, which itself forms the dopant reservoir (and not from the upper semiconductor portion 28, as in FIGS. 2A to 2L).

With reference to FIG. 3A, the interposed semiconductor portion 27 is produced by epitaxial growth directly from the detection portion 10. This step is similar to that of FIG. 2G and differs therefrom in that the interposed semiconductor portion 27 is n+ doped with dopants suitable for n-doping the germanium of the detection portion 10, for example in this case with phosphorus, arsenic, or even silicon or zinc. The interposed semiconductor portion 27 is doped at the growth and not by ion implantation, in order to avoid any degradation of the crystalline quality of the material. Moreover, the dopants do not modify the properties of the material of the interposed semiconductor portion 27 in terms of the lattice parameter. The bandgap energy remains at least 0.5 eV higher than that of the germanium of the detection portion 10. It also should be noted that the temperature of the epitaxy is controlled in order to limit any diffusion of the dopants in the detection portion 10.

With reference to FIG. 3B, the first n+ doped region 11 is produced by carrying out diffusion annealing and activating the dopants. The temperature and the duration of the annealing can be similar to those mentioned above, in relation to FIG. 2I. Thus, the dopants diffuse from the interposed semiconductor portion 27 into the detection portion 10, which forms the first n+ doped region 11.

With reference to FIG. 3C, the metal contacts 32.1 and 32.2 are finally produced. Firstly, a through-opening is produced in the insulating layers 23 and 29, which opening emerges onto the peripheral semiconductor portion 25 and then the silicided zone 31 is produced. A through-opening is then produced in the insulating layer 29, which opening emerges onto the interposed semiconductor portion 27. Finally, a thin attachment layer 33 is deposited in the openings and then the free space is filled with copper 34. The metal contacts 32.1 and 32.2 are thus acquired.

Particular embodiments have been described above. Various alternative embodiments and modifications will become apparent to a person skilled in the art.

1. A photodiode, comprising:
a detection portion, having a first surface and a second surface opposite each other and parallel to a main plane, made of a first germanium-based crystalline semiconductor material, comprising:
a first n-type doped region, and flush with the first surface;
a second p-type doped region, and flush with the second surface;
an intermediate region, located between the first region and the second region and surrounding the first region in the main plane;
a peripheral semiconductor portion, made of a second p-type doped semiconductor material, surrounding the detection portion in the main plane and coming into contact with the second region;
an interposed semiconductor portion, disposed on and in contact with the first region of the detection portion;
metal contacts, disposed on the side of the first surface, and adapted to electrically bias the first region with the interposed semiconductor portion and further adapted to electrically bias the second region with the peripheral semiconductor portion;
wherein the interposed semiconductor portion is made of a third crystalline semiconductor material having:
a natural lattice parameter equal, to within 1%, to a natural lattice parameter of the first germanium-based semiconductor material;
a bandgap energy at least 0.5 eV higher than that of the first germanium-based semiconductor material.

2. The photodiode as claimed in claim 1, wherein the interposed semiconductor portion comprises n-type dopants identical to those present in the first region.

3. The photodiode as claimed in claim 1, wherein the interposed semiconductor portion is made of a III-V crystalline semiconductor compound.

4. The photodiode as claimed in claim 3, wherein the interposed semiconductor portion is made of AlAs or GaAs.

5. The photodiode as claimed in claim 1, wherein the interposed semiconductor portion is located in a notch of the first surface of the detection portion so that the interposed semiconductor portion is surrounded, in the main plane, by the first region.

6. The photodiode as claimed in claim 1, wherein one of the metal contacts, called central metal contact, is located on and in contact with the intermediate semiconductor portion.

7. The photodiode as claimed in claim 1, comprising an upper semiconductor portion located on and in contact with the interposed semiconductor portion, made of an n-type doped semiconductor material with dopants identical to those of the interposed semiconductor portion and of the first region.

8. The photodiode as claimed in claim 7, wherein one of the metal contacts, called central metal contact, is located on and in contact with the upper semiconductor portion.

9. The photodiode as claimed in claim 7, wherein the upper semiconductor portion is made of a material identical to that of the peripheral semiconductor portion.

10. The photodiode as claimed in claim 7, wherein the upper semiconductor portion and the peripheral semiconductor portion are made of a silicon-based semiconductor material and comprises a silicided upper zone in contact with the metal contacts.

11. A method for manufacturing a photodiode as claimed in claim 1, comprising the following steps:
producing a stack comprising a first sub-layer intended to form the second region and a second sub-layer intended to form the intermediate region;
producing an upper insulating layer covering the stack;
producing the peripheral semiconductor portion through the stack and the upper insulating layer in order to emerge onto the first sub-layer;
producing the interposed semiconductor portion by epitaxy from the second sub-layer of the stack, through an opening of the upper insulating layer.

12. The manufacturing method as claimed in claim 11, comprising, before the step of producing the interposed semiconductor portion, a step of producing a notch in the second sub-layer of the stack, through the opening, followed by epitaxy of the interposed semiconductor portion in the notch.

13. The manufacturing method as claimed in claim 11, wherein the interposed semiconductor portion is unintentionally doped during the epitaxy thereof, the method comprising the following steps:
producing the n-type doped upper semiconductor portion;
annealing adapted to cause diffusion of the dopants contained in the upper semiconductor portion through the interposed semiconductor portion in order to form the first region in the detection portion.

14. The manufacturing method as claimed in claim 13, wherein the upper semiconductor portion and the peripheral semiconductor portion are made of the same silicon-based material, the method further comprising the following step:
simultaneously producing metal contacts, one in contact with the upper semiconductor portion, and the other in contact with the peripheral semiconductor portion.

15. The manufacturing method as claimed in claim 11, wherein the interposed semiconductor portion is n-type doped during the epitaxy thereof, the method comprising the following step:
producing metal contacts, one in contact with the interposed semiconductor portion, and the other in contact with the peripheral semiconductor portion.
